(19) United States
(12) Patent Application Publication
(10) Pub. No.: US 2023/0336322 A1
(43) Pub. Date: Oct. 19, 2023

(54) MULTI-LEVEL PULSING SYSTEM

(71) Applicant: Advanced Energy Industries, Inc., Denver, CO (US)

(72) Inventors: Jeffrey Roberg, Longmont, CO (US); Eugene Pakenham, Loveland, CO (US)

(21) Appl. No.: 18/302,294

(22) Filed: Apr. 18, 2023

Related U.S. Application Data
(60) Provisional application No. 63/332,139, filed on Apr. 18, 2022.

(51) Int. Cl. H04L 7/00; H04L 7/08; H04L 7/06

(52) U.S. Cl. CPC H04L 7/0008; H04L 7/08; H04L 7/06

(57) ABSTRACT

A synchronization module is configured to generate a synchronization signal for transmission to at least one of a power generator and/or at least one match network, wherein the synchronization signal is formed with pulses having varying durations, wherein a duration of a pulse in the synchronization signal conveys information about an event in a power waveform.

### CLAIM OF PRIORITY UNDER 35 U.S.C. § 119

This application claims the benefit of priority of provisional application No. 63/332,139, entitled Multi-Level Pulsing System filed on Apr. 18, 2022, which is incorporated herein by reference.

### FIELD OF THE DISCLOSURE

This disclosure relates generally to power supply systems. In particular, but not by way of limitation, this disclosure relates to the interoperation of power system components.

### BACKGROUND

Power supply systems, including power supplies and match networks, are used in a variety of contexts including semiconductor processing. Semiconductor processing and other advanced material processing rely on increasingly sophisticated plasma processes. Such plasma processes, in turn, require increasingly sophisticated power systems and control systems, to subject inherently unstable and nonlinear plasmas to increasing precision and consistency. Such plasmas are used for processes such as plasma etch processes, plasma-enhanced chemical vapor deposition (CEPVD) processes, plasma-enhanced atomic layer deposition (PEALD) processes, plasma-assisted atomic-layer deposition (PA-ALD), RF sputtering deposition, and other plasma processing applications.

In some plasma processing recipes, it is desirable to apply a pulsed and/or a multi-level power waveform having multiple states and/or levels, such as exemplary pulsed waveform 50 of FIG. 1. The different states may indicate, for example and without limitation, different power levels and/or different frequencies. The waveform may include one or more cycles. In FIG. 1, waveform 50 has a first cycle 60, a transition cycle 61, and a second cycle 62. Within each cycle there may be one or more sequences of power states. In power waveform 50 of FIG. 1, for example, first pulse cycle 60 has six repeating sequences with three power states (states 1-3) per sequence, and second pulse cycle 62 has four repeating sequences with four power states (states 1-4) per sequence.

It is noted that in a power waveform such as that shown in FIG. 1, a “sequence” having multiple power states is sometimes alternatively referred to as a multilevel “pulse,” which is why a waveform such as that depicted in FIG. 1 is sometimes referred to as a multilevel pulsed waveform. Although not shown in FIG. 1, a power level of zero is also a state. As will become apparent below, however, this disclosure involves synchronization signals that are also configured with pulses. To avoid confusion between this terminology, the following description uses the terminology “sequence” when referring to the power waveform and uses the terminology “pulse” when referring to a synchronization signal.

Power generators need to support power waveforms such as waveform 50 having multiple states, with each state having independent control parameters such as power setpoint and frequency. Power generators are commonly used with match networks to optimize delivery of the power waveform to the plasma processing chamber. The match network is typically coupled between the power generator and the plasma processing chamber and adjusts its impedance as needed to reduce reflected power. It is important that the matching network be synchronized to any changes in the power signal, such as the state changes that occur in a pulsed waveform having multiple cycles comprised of multiple sequences having multiple states.

Process results may be degraded if the system components (such as generators and match networks) are not coordinated and synchronized. A tune point may be characterized as the frequency at which the input impedance of the match network matches the output impedance of the power generator. If not coordinated and synchronized, the match network can oscillate between optimal tune points for different states. Current match functionality supports only a single-wire signal to support two pulse states. Process results may be degraded in a multilevel pulsing system if the impedance is tuned to one state only. Moreover, match networks in typical systems are unable to report information on a state-by-state basis because match networks typically do not know when each state starts and stops.

### SUMMARY

One aspect of this disclosure is a power generator that comprises a power generation component configured to generate a power waveform for transmission to a secondary component and a synchronization component configured to generate a synchronization signal for transmission to the secondary component. The synchronization signal is formed with pulses having varying durations, and a duration of a pulse in the synchronization signal conveys information to the secondary component about an event in the power waveform.

In one implementation, the secondary component is a matching network interposed between the power generator and a plasma processing chamber.

In another implementation, the duration of the pulse in the synchronization signal conveys information about a change in a state of the power waveform.

In a further implementation, a first pulse of a first duration in the synchronization signal indicates that the state is ending and that a next state in a same sequence of a same cycle of the power waveform is beginning.

In a further implementation, a second pulse of a second duration in the synchronization signal indicates that a last state of a particular repeating sequence is ending and that a first state in the same particular repeating sequence of the same cycle of the power waveform is beginning.

In a further implementation, a third pulse of a third duration indicates that the state is ending and that the next state in a first sequence of a next cycle of the power waveform is beginning.

In a further implementation, a threshold time of inactivity after a pulse is initiated signals the power is off.

Another aspect of this disclosure is a match network that has an input configured to receive a power waveform from a primary component, and a synchronization component configured to receive a synchronization signal from the primary component. The synchronization signal is formed with pulses having varying durations, and a duration of a pulse in the synchronization signal conveys information to the match network about an event in the power waveform.

A further aspect of this disclosure is a plasma processing system comprising at least one match network and at least one power generator. The power generator is configured to generate and transmit a power waveform to the match network. The system also comprises a synchronization component configured to generate a synchronization signal for transmission to the power generator and/or the match network. The synchronization signal is formed with pulses having varying durations, and a duration of a pulse in the synchronization signal conveys information about an event in the power waveform to the match network.

Further aspects of this disclosure are depicted in the accompanying drawings and description and will be apparent based thereon.

### BRIEF DESCRIPTION OF THE DRAWINGS

FIG. 1 is a conceptual diagram of an exemplary multi-level pulsed power waveform, in accordance with this disclosure.

FIG. 2A is a block diagram of an exemplary plasma processing system, in accordance with this disclosure.

FIG. 2B is a block diagram of another exemplary plasma processing system, in accordance with this disclosure.

FIG. 3 is a timing diagram showing a synchronization signal for various states of a multi-level power waveform, in accordance with this disclosure.

FIG. 4 is a first segment of a timing diagram showing three synchronization signals for various states of three multi-level pulsed power waveforms, in accordance with this disclosure.

FIG. 5 is a second segment of a timing diagram showing three synchronization signals for various states of three multi-level pulsed power waveforms, in accordance with this disclosure.

FIG. 6 is a third segment of a timing diagram showing three synchronization signals for various states of three multi-level pulsed power waveforms, in accordance with this disclosure.

FIG. 7 is a conceptual block diagram depicting a computing system that may be utilized in connection with embodiments disclosed herein.

### DETAILED DESCRIPTION

The word “exemplary” is used herein to mean “serving as an example, instance, or illustration.” Any embodiment described herein as “exemplary” should not be construed as preferred or advantageous over other embodiments.

Preliminary note: the flowcharts and block diagrams in the following drawings illustrate the architecture, functionality, and operation of possible implementations of systems, methods, and computer program products according to various embodiments of this disclosure. In this regard, some blocks in the flowcharts and block diagrams may represent a module, segment, or portion of code, which comprises one or more executable instructions for implementing the specified logical function(s). In some implementations, the functions noted in the block may occur out of the order set forth in the drawings. For example, two blocks shown in succession may, in fact, be executed substantially concurrently, or be executed in the reverse order, depending upon the functionality involved. It will also be understood that each block and combinations of blocks in the flowcharts and block diagrams can be implemented by special purpose hardware-based systems that perform the specified functions or acts, or combinations of special purpose hardware and computer instructions.

Although the terms first, second, third etc. may be used herein to describe various elements, components, regions, layers and/or sections, it will be understood that these elements, components, regions, layers and/or sections are not limited by these terms. These terms are only used to distinguish one element, component, region, layer or section from another region, layer, or section. Thus, a first element, component, region, layer, or section discussed below could be termed a second element, component, region, layer, or section without departing from the teachings of this disclosure.

The terminology used herein is for the purpose of describing particular embodiments only and is not intended to limit this disclosure. As used herein, the singular forms “a,” “an,” and “the” are intended to include the plural forms as well, unless the context clearly indicates otherwise. The terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes all combinations of one or more of the associated listed items and may be abbreviated as “/”.

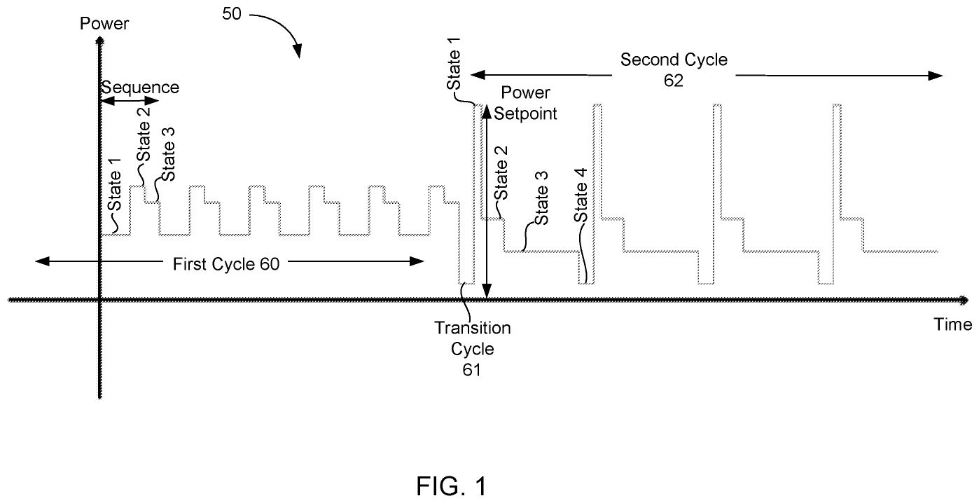

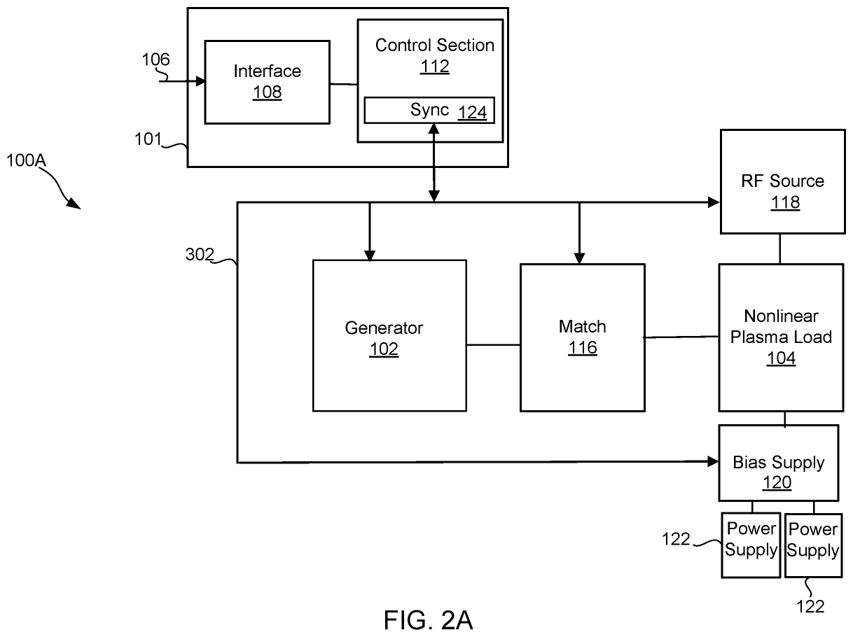

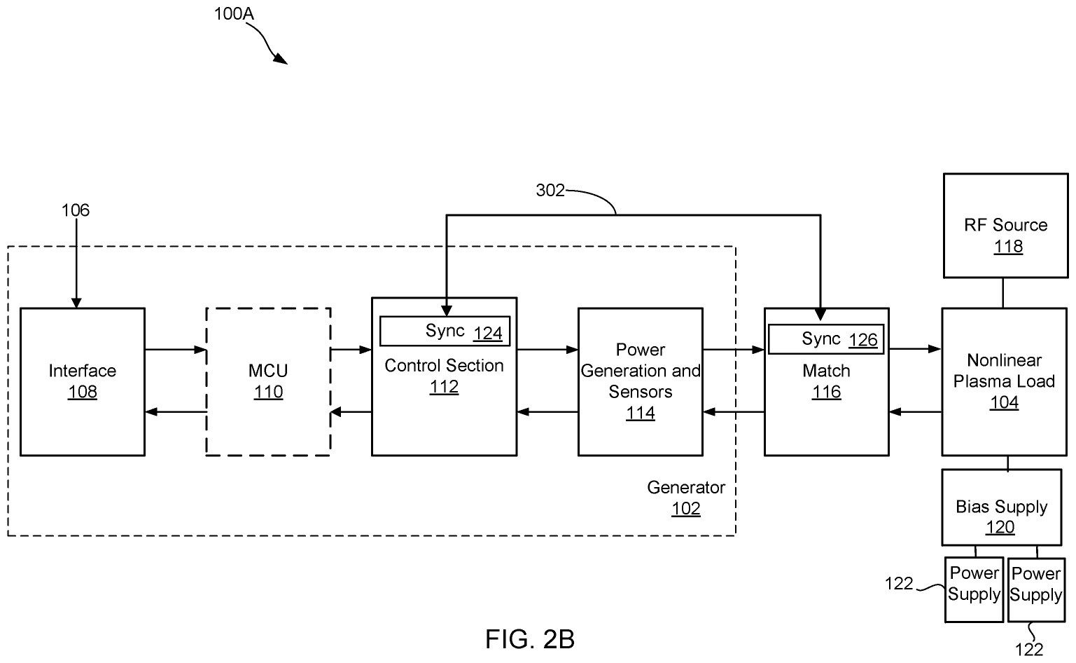

FIG. 2A is a block diagram of an exemplary plasma processing system 100 comprising components including a generator 102 for providing a variety of types of power waveforms to a nonlinear and/or chaotic plasma load 104 based on an input 106, where the input may arrive from a person, another controller, or from another control construct within system 100A. The types of power waveforms generated by generator 102 may include multilevel waveforms such as waveform 50 of FIG. 1, and a power level of each state may be defined by the input 106. It should be recognized that the states depicted in FIG. 1 may be power levels, and within each state, the generator 102 may apply many cycles of an RF voltage (e.g., a sinusoidal voltage) at frequencies of, for example and without limitation, 13.56 MHz and 60 MHz. For clarity, the high frequency voltage waveforms are not depicted. It should also be recognized that power is used as an example attribute throughout this disclosure, but each state may be defined by other attributes.

Other components depicted in FIG. 2A include match network 116, RF source 118, bias supply 120 and power supplies 122 coupled to bias supply 120. The high-level components in FIG. 2A may include lower-level constructs (subcomponents of the higher-level constructs) such as, for example and without limitation, DC rail supplies, RF amplifiers, variable capacitors, and direct current (DC) power supplies within bias supply 120. In general, FIG. 2A depicts a multi-component and multi-control-knob nonlinear system, and aspects of this disclosure detailed further herein relate to control over the multi-actuator and multi-control-knob system.

As shown, a centralized controller 101 comprises an interface to receive and process the input signal 106 and a control section 112 to provide one or more control signals based upon the input signal 106. As shown, the control section 112 includes a primary synchronization module (“Sync”) 124 that is coupled to a synchronization line 302, and the synchronization line 302 may be coupled to the components in the system 100A to provide a synchronization signal as described further herein. In some embodiments, at a physical layer, the synchronization line 302 may be a single wireline connection, but this is not required.

According to one aspect of this disclosure, the synchronization signal disclosed herein conveys information that enables the components of the system 100A to quickly respond to changing events within the system 100A. For example, the synchronization signals disclosed herein may convey information about events occurring in a power waveform applied by the generator 102. More specifically, the synchronization signal applied to the synchronization line may be formed with pulses having varying durations, wherein the duration of the pulse conveys information about events such as, for example and without limitation, a change of state within a sequence, a completion of a sequence and the beginning of a new state in the next sequence, or a completion of a cycle and the beginning of a new state in the next cycle.

Although the primary synchronization module 124 may be implemented in a centralized controller 101 as shown in FIG. 2A, it may also be implemented in one or more other components. For example, FIG. 2B depicts a system 100B that is a variation of the system 100A in which the generator 102 comprises the primary synchronization module 124. As shown, FIG. 2B includes additional details of subcomponents that may be implemented in generator 102. For example, generator 102 includes the user interface 108, an optional master control unit (MCU) 110, control section 112 (e.g., an FPGA, CPU, or combination of FPGA and CPU), and a power generation component and sensors 114.

As shown, the control section 112 of generator 102 comprises primary synchronization module (“Sync”) 124 coupled to secondary synchronization module (“Sync”) 126 of match network 116 via the synchronization line 302, which propagates the synchronization signal to provide the synchronization signal to match network 116. Coordination between match network 116 and generator 102 is thereby enabled to prevent or mitigate against oscillation of match network 116 between optimal tune points for the power states that are applied to plasma load 104. Moreover, in some implementations the synchronization signal may enable the impedance of match network 116 to be changed on a per-state basis, thereby enabling the impedance of match network 116 to be separately tuned during multiple states and enabling increasingly faster embodiments of match network 116 to be realized. In this regard, some embodiments of match network 116 may be realized by solid-state switching components that may be switched at very high speeds to enable the impedance of match network 116 to be changed at very high speeds, utilizing synchronization signal 302, on a per-pulse basis. But the match network 116 may be implemented utilizing variable vacuum capacitors in some embodiments.

According to one aspect of this disclosure, the synchronization signal conveys information to match network 116 about the power waveform generated by generator 102. In particular, synchronization signal conveys information about events occurring in the power waveform. More particularly, synchronization signal may be formed with pulses having varying widths or durations, wherein the width or duration of the pulse conveys information about events such as a change of state within a sequence, a completion of a sequence and the beginning of a new state in the next sequence, or a completion of a cycle and the beginning of a new state in the next cycle.

It should be recognized that FIGS. 2A and 2B are only examples and that the primary synchronization module 124 may be instantiated within a housing of any of the components depicted in FIGS. 2A and 2B.

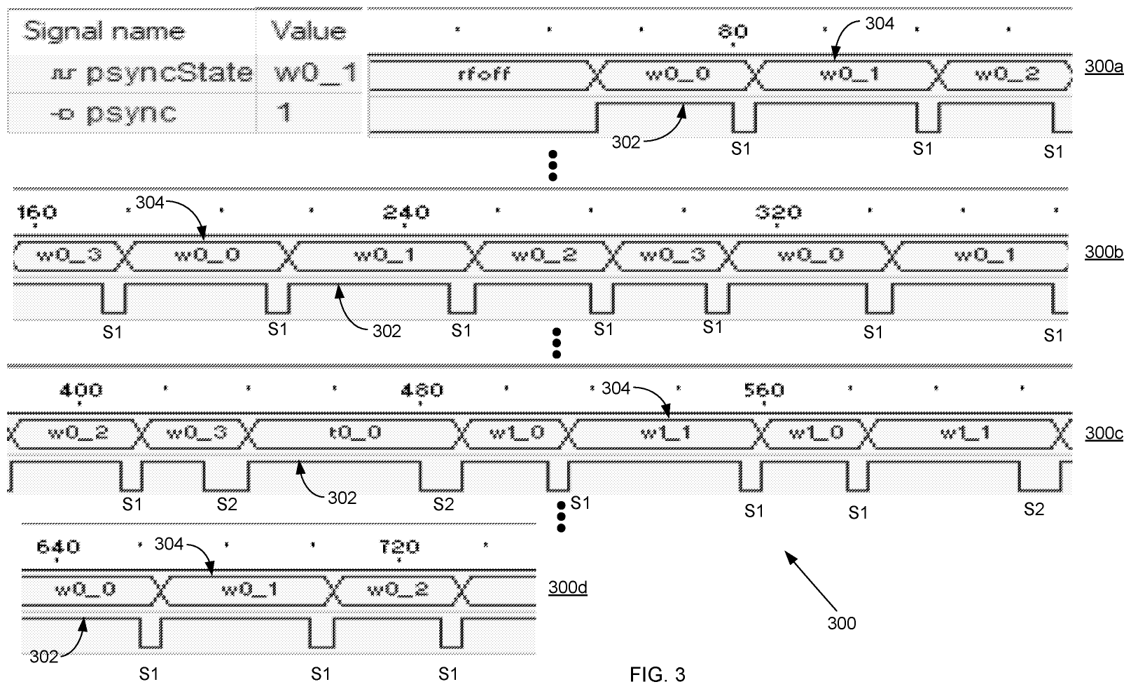

FIG. 3 is a timing diagram 300 showing an exemplary synchronization signal “psync” configured to synchronize match network 116 to various states 304 (designated in FIG. 3 as “psyncState”) of a multi-level pulsed power waveform, in accordance with this disclosure. Timing diagram 300 illustrates a single synchronization signal 302 running from time 0 μs (beginning of top segment 300a) to time 760 μs (end of bottom segment 300d). Due to drawing and font size limitations, timing diagram 300 is split into four segments 300a-300d. The right side of top segment 300a is continuous with the left side of second segment 300b (at about 160 μs); the right side of second segment 300b is continuous with the left side of third segment 300c (at about 380 μs); and the right side of third segment 300c is continuous with the left side of bottom segment 300d (at about 640 μs).

The power waveform represented by states 304 (“psyncState”) of FIG. 3 has a first cycle w0, and a second cycle w_1. First cycle w0 has three sequences, with each sequence having four states: w0_0, w0_1, w0_2, and w0_3. Second cycle w1 has two sequences, with each sequence having two states: w1_0 and w1_1. There is a transition state t0 following the first cycle w0. The durations of the four states of the sequences of the first cycle w0 are: 35 μs (w0_0); 40 μs (w0_1); 30 μs (w0_2); and 25 μs (w0_3). The durations of the two states of the sequences of the second cycle w1 are: 25 μs (w1_0) and 45 μs (w1_1). Transition state t0 is essentially a transition cycle having a single state t0_0 with a duration of 50 μs. In the power waveform represented by states 304 of FIG. 3, the number of cycles, the number of sequences per cycle, the number of states per sequence, and the durations of the states, are arbitrary and represent merely one non-limiting example of many possible waveform configurations.

Synchronization signal 302 (“psync”) generally has two levels: a first level that indicates that a power waveform is active or on; and a second level that conveys information about events occurring in the power waveform. The first level is shown generally and for non-limiting purposes of illustration in FIG. 3 as a “high” level; and the second level is shown generally and for non-limiting purposes of illustration in FIG. 3 as a “low” level. The second level of synchronization signal 302 is configured in short pulses of varying width or duration that, based on the width or duration of the pulse, communicates information about events (state changes) in the power waveform.

Synchronization signal 302 of FIG. 3 includes two types of pulses for communicating state change information. First pulses S1 have a first duration and communicate that a state is about to end and that a new state within a repeating sequence of the same cycle is about to begin. Second pulses S2 have a second duration and communicate that a state is about to end and that a new state within a new cycle is about to begin. In FIG. 3, for non-limiting purposes of illustration only, the first duration of first pulses S1 is 5 μs, and the second duration of second pulses S2 is 10 μs. These pulse durations are arbitrary and could have many other values, so long as they are different from each other. Thus, first pulse S1 of synchronization signal 302 indicates to the receiver (here, match network 116) that it should advance to the next state within a repeating sequence of the same cycle, while second pulse S2 indicates to the receiver that it should advance to the next state in the next new cycle. In some implementations, each event is defined with a duration, that has a tolerance. For example and without limitation, a tolerance may be +/−1 microsecond.

As previously described, first cycle w0 of the waveform has three sequences, with each sequence having four states: w0_0, w0_1, w0_2, and w0_3. Thus, synchronization signal 302 communicates each upcoming state change within the first cycle w0 except for the last state change (third occurrence of w0_3) using pulse S1, thereby communicating to match network 116 that a change to a new state within the same cycle of repeating sequences is upcoming. Near the end of the last state (third occurrence of w0_3) within the first cycle w0, synchronization signal 302 communicates the upcoming state change to transition state t0_0 using pulse S2, thereby communicating to match network 116 that a change to a new state within a new cycle is upcoming.

Transition state t0_0 is a cycle having a single state, so near the end of transition state t0_0, synchronization signal 302 communicates another upcoming state change to the second cycle w1 using pulse S2, thereby communicating that a change to a new state within a new cycle is upcoming. Second cycle w1 has two sequences, with each sequence having two states: w1_0 and w1_1. Thus, synchronization signal 302 communicates each upcoming state change within second cycle w1 except for the last state change (second occurrence of w1_1) using pulse S1, thereby communicating that a change to a new state within the same cycle of repeating sequences is upcoming. Near the end of the last state (second occurrence of w1_1) within second cycle w1, synchronization signal 302 communicates the upcoming state change back to first cycle w0 (no transition state in this example) using pulse S2, thereby communicating to match network 116 that a change to a new state within a new cycle is upcoming. First cycle w0 then begins again with state changes within first cycle w0 being indicated by pulse S1.

FIG. 3 depicts a synchronization signal that utilizes two pulses S1 and S2 having different widths or durations to communicate two types of events within the multi-level power waveform: pulse S1 of one duration communicates a change to a new state within the same cycle of repeating sequences and pulse S2 of another duration communicates a change to a new state within a new cycle. Additional types of pulses having different durations may be used to communicate additional events beyond these two types. A third pulse having a third duration may be used to indicate that the last state of a particular repeating sequence in a cycle is completing, and that the first state of the same particular repeating sequence in the same cycle is upcoming. A fourth pulse having a fourth duration may be used to communicate that a state is finishing, and that the receiver should go back one step. This may be used to support “pulse-in-pulse” functionality where the cycle has some repetition of states before moving onto new states. For instance, in the state sequence w0_0, w0_1, w0_0, w0_1, w0_0, w0_1, w0_2, w0_3, there are four states, but the first two states repeat three times before continuing with the third and fourth states. And when synchronization signal has been at the second or low level for some time greater than a predetermined threshold, OFF is detected, i.e., no power waveform is being generated. This is shown in FIG. 3 between 0 μs and 50 μs of synchronization signal 302. This mode of operation is beneficial to keep the system in a safe state when there is an issue with the synchronization signal.

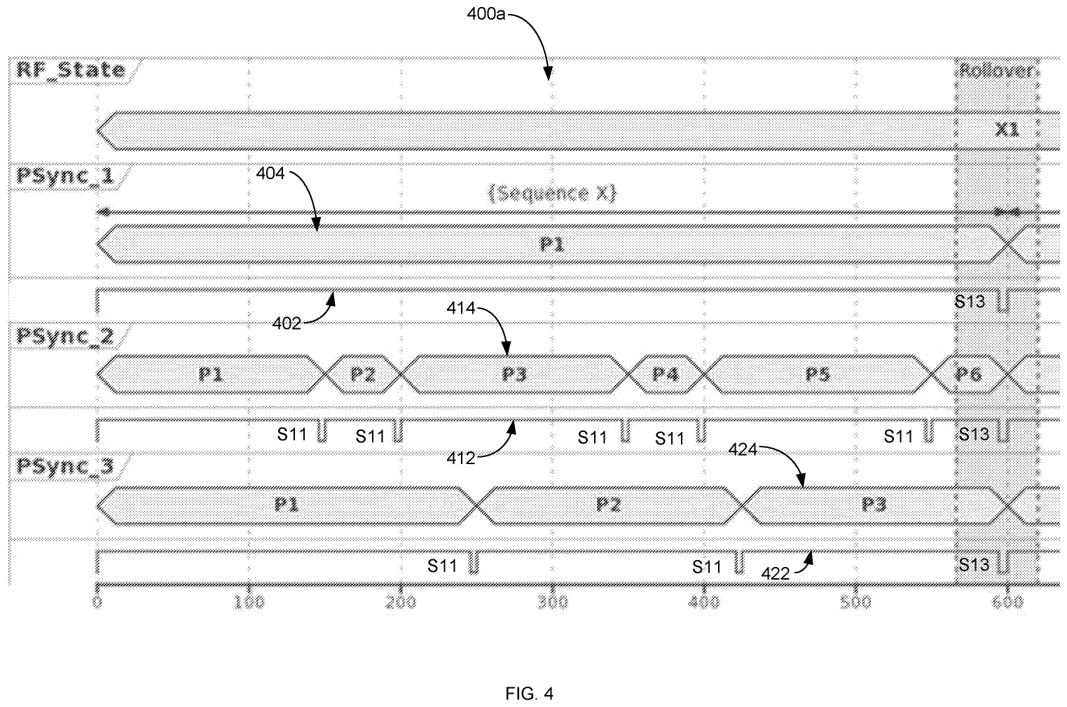

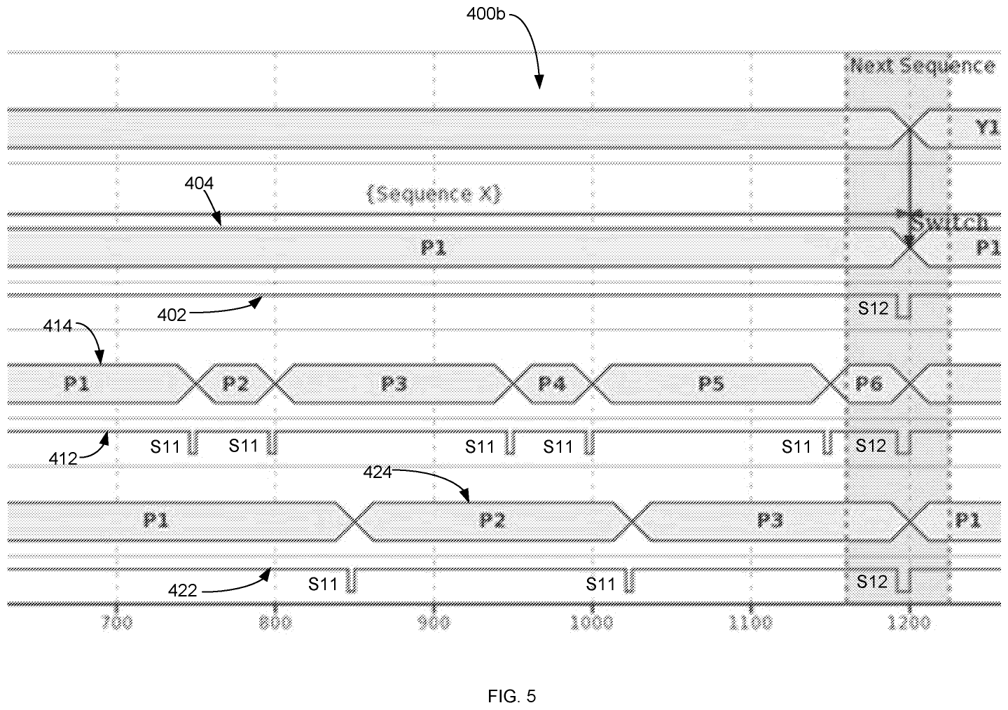

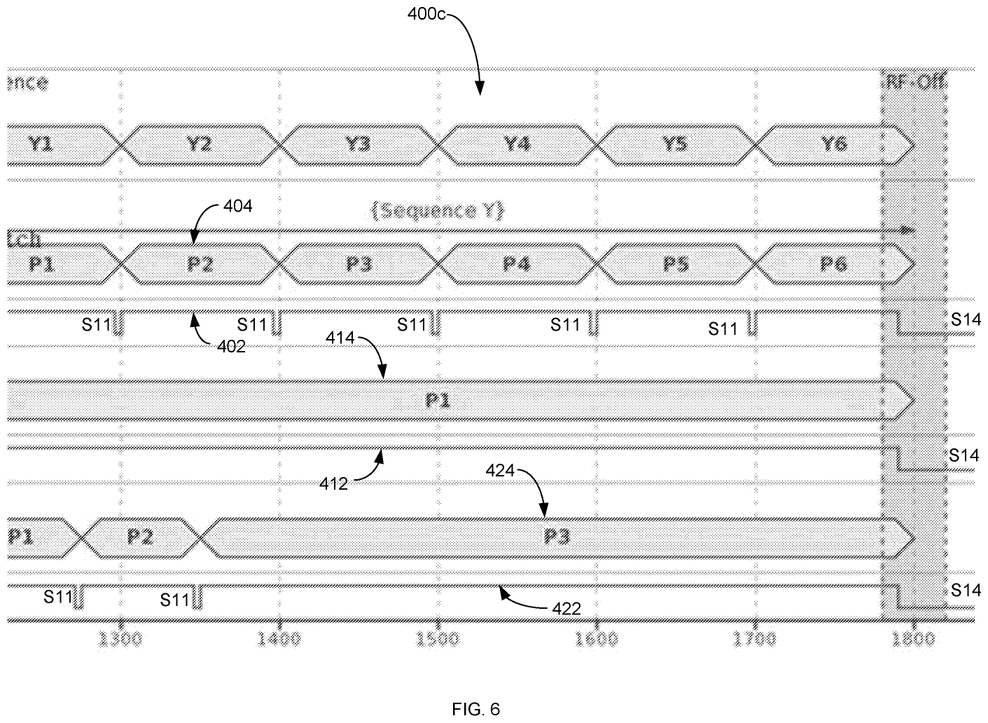

FIGS. 2 and 3 illustrate an example in which primary synchronization module 124 of generator 102 produces a single synchronization signal 302 that is provided to secondary synchronization module 126 of match network 116. But in other examples, it may be desirable that the primary synchronization module produce multiple synchronization signals that may be used to synchronize multiple secondary components. Such an example is depicted in the timing diagram of FIGS. 4-6. Due to drawing and font size limitations, the timing diagram of FIGS. 4-6 is split into three segments: first segment 400a, from 0 μs to about 600 μs (FIG. 4); second segment 400b, from about 600 μs to about 1200 μs (FIG. 5); and third segment 400c, from about 1200 μs to 1800 μs (FIG. 6). Thus, the right side of first segment 400a is continuous with the left side of second segment 400b, and the right side of second segment 400b is continuous with the left side of third segment 400c.

First synchronization signal 402 is configured to synchronize a first component (a match network or another generator, for example) to a first power waveform represented by states 404 (“PSync_1”). Second synchronization signal 412 is configured to synchronize a second component (a match network or another generator, for example) to a second power waveform represented by states 414 (“PSync_2”). Third synchronization signal 422 is configured to synchronize a third component (a match network or another generator, for example) to a third power waveform represented by states 424 (“PSync_3”). Although the frequency of the first, second and third waveforms may vary in some use cases the frequency of these waveforms is a radio frequency (RF) frequency (for example and without limitation, 13.56 MHz).

Each of the power waveforms represented by states 404, 414, 424 of FIGS. 4-6 has two cycles. The first cycle begins at 0 μs and ends at 1200 μs (FIGS. 4 and 5), and the second cycle begins at 1200 μs and ends at 1800 μs (FIG. 6). The first cycle has two repeating sequences: a first repeating sequence that begins at 0 μs and ends at 600 μs (FIG. 4); and a second repeating sequence that begins at 600 μs and ends at 1200 μs (FIG. 5). The second cycle comprises one sequence that begins at 1200 μs and ends at 1800 μs (FIG. 6).

The first power waveform represented by states 404 (“PSync_1”) has one state P1 in the repeating sequences of its first cycle (FIGS. 4 and 5) and has six states P1-P6 in the sequence of its second cycle (FIG. 6). The second power waveform represented by states 414 (“PSync_2”) has six states P1-P6 in the repeating sequences of its first cycle (FIGS. 4 and 5) and has one state P1 in the sequence of its second cycle (FIG. 6). The third power waveform represented by states 424 (“PSync_3”) has three states P1-P3 in the repeating sequences of its first cycle (FIGS. 4 and 5) and has three states P1-P3 in the sequence of its second cycle (FIG. 6).

In a similar manner as described with reference to FIG. 3, synchronization signals 402, 412, 422 of FIGS. 4-6 generally have two levels: a first level that indicates that a power waveform is present; and a second level that conveys information about events occurring in the power waveform. The first level is shown generally as a “high” level and the second level is shown generally as a “low level”. The second level comprises short pulses of varying width or duration that, based on the width or duration of the pulse, communicates information about events (state changes) in the power waveform.

Synchronization signals 402, 412, 422 of FIGS. 4-6 include four example types of short pulses for communicating state change information. First pulses S11 have a first duration and communicate that a state is about to end and that a new state within the same sequence is about to begin. Second pulses S12 have a second duration and communicate that a state is about to end and that a new state within a sequence of a new cycle is about to begin. In FIG. 5, the transition communicated by second pulses S12 is also referred to as “Next Sequence.” Third pulses S13 indicate that a state is about to end and that a new state within the next repeating sequence of the same cycle is about to begin. In FIG. 4, the transition communicated by third pulses S13 is also referred to as “Rollover.” Fourth pulses S14 indicate that the power waveform has turned off. In FIGS. 4-6, for non-limiting purposes of illustration only, the first duration of first pulses S11 is 4 μs, the second duration of second pulses S12 is 6 μs, the third duration of third pulses S13 is 8 μs, and the fourth duration of fourth pulses S14 is 10 μs. These pulse durations are arbitrary and could have many other values, so long as they are different from each other.

As mentioned above, each of the three waveforms respectively depicted by states 404, 414, 424 has a first cycle comprising two repeating sequences, with the first repeating sequence being shown in FIG. 4 and the second repeating sequence being shown in FIG. 5, and a second cycle having one sequence as shown in FIG. 6.

With reference to FIG. 4, the first waveform represented by states 404 has only one state P1 in the repeating sequences of the first cycle. Thus, first synchronization signal 402 uses pulse S13 at the end of state P1 to communicate that the state is about to end and that a new state in the next repeating sequence of the same cycle is about to begin. The second waveform represented by states 414 has six states P1-P6 in the repeating sequences of the first cycle. Thus, second synchronization signal 412 uses pulse S11 at the ends of states P1-P5 to communicate that that state is about to end and that a new state in the same sequence is upcoming and uses pulse S13 at the end of state P6 to communicate that the state is about to end and that a new state in the next repeating sequence of the same cycle is about to begin. The third waveform represented by states 424 has three states P1-P3 in the repeating sequences of the first cycle. Thus, second synchronization signal 412 uses pulse S11 at the ends of states P1 and P2 to communicate that the state is about to end and that a new state in the same sequence is upcoming and uses pulse S13 at the end of state P3 to communicate that the state is about to end and that a new state in the next repeating sequence of the same cycle is about to begin.

With reference to FIG. 5, the three waveforms repeat the same sequence as in FIG. 4, but at the end of that repeated sequence a new cycle begins, which is communicated by use of pulse S12 in the synchronization signals. Thus, first synchronization signal 402 uses pulse S12 at the end of state P1 to communicate that the state is ending and that a new state in the first sequence of the next cycle is about to begin. Second synchronization signal 412 uses pulse S11 at the ends of states P1-P5 to communicate that the state is ending and that a new state in the same sequence is upcoming and uses pulse S12 at the end of state P6 to communicate that the state is ending and that a new state in the first sequence of the next cycle is about to begin. Third synchronization signal 422 uses pulse S11 at the ends of states P1 and P2 to communicate that that state is ending and that a new state in the same sequence is upcoming and uses pulse S12 at the end of state P3 to communicate that the state is ending and that a new state in the first sequence of the next cycle is about to begin.

With reference to FIG. 6, the three waveforms begin a second (new) cycle. In the second cycle, each waveform has one sequence. The first waveform represented by states 404 has six states P1-P6 in its sequence; the second waveform represented by states 414 has one state P1 in its sequence; and the third waveform represented by states 424 has three states P1-P3 in its sequence. At the end of the second cycle shown in FIG. 6, the power waveform is ended or turned off, which is indicated in the synchronization signals by pulse S14. Thus, synchronization signal 402 includes pulses S11 at the ends of states P1-P5 and pulse S14 at the end of state P6; synchronization pulse 412 includes pulse S14 at the end of its only state P1; and synchronization pulse 422 includes pulse S11 at the ends of states P1 and P2 and pulse S14 at the end of state P3.

If a number of states changes on the secondary component that receives the synchronization signal (e.g., match network 116) for the sequence that is active, that number of states may be latched and then later applied when the sequence completes (this helps avoid issues for sequences such as when the primary component (e.g., synchronization module 124 of generator 102) is told to toggle waveforms, but there is a delay for the actual toggle in order for the in-process waveform to be completed.

The secondary synchronization component (e.g., match network 116) can detect loss of synchronization, and if the primary synchronization component (e.g., generator 102) is constrained to not change duration while running, the secondary component can detect if the same state is received with a different duration. In addition, the secondary component can detect if an ending pulse was not received during the last state of a sequence (e.g., pulses S2, S12). For states that are indefinite, there is a predetermined delay (in one example, 10 μs) from exit stimulus until the state changes. Also, if a waveform switch request is received within a predetermined time (in one example, 10 μs) of the end of the last state, that request will be delayed until the next repetition of the sequence is completed.

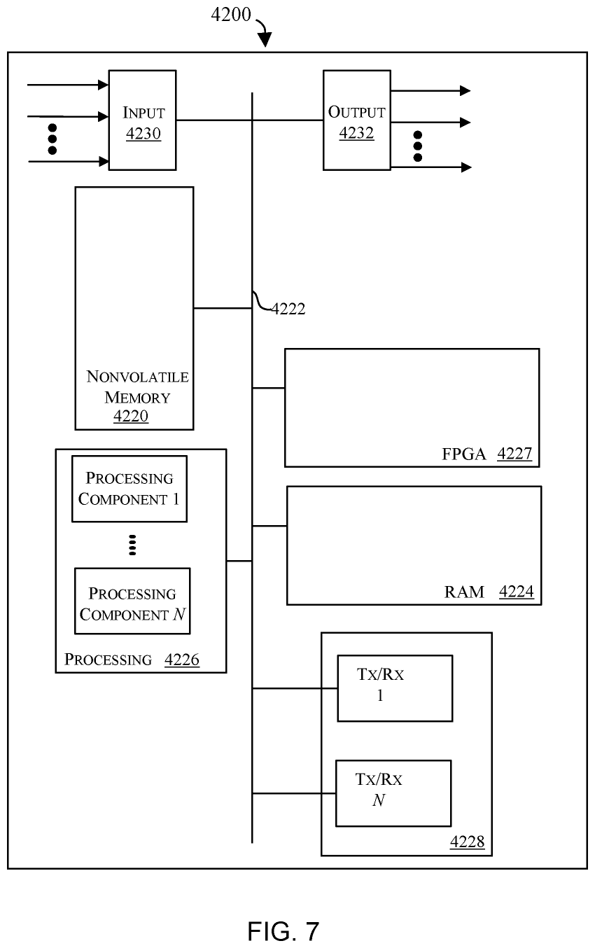

The methods described in connection with the embodiments disclosed herein may be embodied directly in hardware, in processor-executable code encoded in a non-transitory tangible processor readable storage medium, or in a combination of the two. Referring to FIG. 7 for example, shown is a block diagram 4200 depicting physical components that may be utilized to realize primary synchronization module 124 and/or secondary synchronization module 126 of match network 116. More specifically, the collection of components depicted in FIG. 7 may be instantiated in generator 102 and/or match network 116.

As shown, nonvolatile memory 4220 is coupled to bus 4222 that is also coupled to random access memory (“RAM”) 4224, processing portion 4226 that includes N processing components, field programmable gate array (FPGA) 4227, and transceiver component 4228 that includes N transceivers. None of these components are required, and any combination of these may be included in the systems disclosed herein. For instance, where FPGA 4227 is implemented, processing portion 4226 may not be used, and vice versa. Although the components depicted in FIG. 7 represent physical components, FIG. 7 is not intended to be a detailed hardware diagram; thus, many of the components depicted in FIG. 7 may be realized by common constructs or distributed among additional physical components. Moreover, it is contemplated that other existing and yet-to-be developed physical components and architectures may be utilized to implement the functional components described with reference to FIG. 7.

In general, nonvolatile memory 4220 is non-transitory memory that functions to store (e.g., persistently store) data and processor-executable code (including executable code that is associated with effectuating the methods described herein). In some embodiments, nonvolatile memory 4220 includes bootloader code, operating system code, file system code, and non-transitory processor-executable code to facilitate the execution of a method to coordinate operation of generator 102 and match network 116 as described herein.

In many implementations, nonvolatile memory 4220 is realized by flash memory (e.g., NAND or ONENAND memory), but it is contemplated that other memory types may be utilized as well. Although it may be possible to execute the code from nonvolatile memory 4220, the executable code in the nonvolatile memory is typically loaded into RAM 4224 and executed by one or more of the N processing components in processing portion 4226.

The N processing components in connection with RAM 4224 generally operate to execute the instructions stored in nonvolatile memory 4220 to enable a method for coordinating operation of generator 102 and match network 116. For example, non-transitory, processor-executable code to effectuate the methods described herein may be persistently stored in nonvolatile memory 4220 and executed by the N processing components in connection with RAM 4224. As one of ordinarily skill in the art will appreciate, processing portion 4226 may include a video processor, digital signal processor (DSP), micro-controller, graphics processing unit (GPU), or other hardware processing components or combinations of hardware and software processing components (e.g., an FPGA or an FPGA including digital logic processing portions).

In general, input component 4230 operates to receive signals such as synchronization signal 302 corresponding to a multi-level pulsed power waveform applied by generator 102. The signals received at input component 4230 may include, for example, signals depicted in FIGS. 3-6, which may be digital or analog signals. The output component generally operates to provide one or more analog or digital signals corresponding to the signals depicted in FIGS. 3-6.

Transceiver component 4228 includes N transceiver chains, which may be used for communicating with external devices via wireless or wireline networks. Each of the N transceiver chains may represent a transceiver associated with a particular communication scheme (e.g., WiFi, Ethernet, Profibus, etc.).

Some portions are presented in terms of algorithms or symbolic representations of operations on data bits or binary digital signals stored within a computing system memory, such as a computer memory. These algorithmic descriptions or representations are examples of techniques used by those of ordinary skill in the data processing arts to convey the substance of their work to others skilled in the art. An algorithm is a self-consistent sequence of operations or similar processing leading to a desired result. In this context, operations or processing involves physical manipulation of physical quantities. Typically, although not necessarily, such quantities may take the form of electrical or magnetic signals capable of being stored, transferred, combined, compared, or otherwise manipulated. It has proven convenient at times, principally for reasons of common usage, to refer to such signals as bits, data, values, elements, symbols, characters, terms, numbers, numerals, or the like. It should be understood, however, that all of these and similar terms are to be associated with appropriate physical quantities and are merely convenient labels. Unless specifically stated otherwise, it is appreciated that throughout this specification discussions utilizing terms such as “processing,” “computing,” “calculating,” “determining,” and “identifying” or the like refer to actions or processes of a computing device, such as one or more computers or a similar electronic computing device or devices, that manipulate or transform data represented as physical electronic or magnetic quantities within memories, registers, or other information storage devices, transmission devices, or display devices of the computing platform.

As will be appreciated by one skilled in the art, aspects of the present invention may be embodied as a system, method, or computer program product. Accordingly, aspects of the present invention may take the form of an entirely hardware embodiment, an entirely software embodiment (including firmware, resident software, micro-code, etc.) or an embodiment combining software and hardware aspects that may all generally be referred to herein as a “circuit,” “module” or “system.” Furthermore, aspects of the present invention may take the form of a computer program product embodied in one or more computer readable medium(s) having computer readable program code embodied thereon.

As used herein, the recitation of “at least one of A, B and C” or “at least one of A, B or C” is intended to mean “either A, B, C or any combination of A, B and C.” This description is provided to enable any person skilled in the art to make or use the present disclosure. Various modifications to these embodiments will be readily apparent to those skilled in the art, and the generic principles defined herein may be applied to other embodiments without departing from the spirit or scope of the disclosure. Thus, the scope of this disclosure is not limited to the embodiments shown herein but is to be accorded the widest scope consistent with the principles and novel features disclosed herein.

This disclosure is provided to enable any person skilled in the art to make or use the embodiments described herein. Various modifications will be readily apparent to those skilled in the art, and the principles disclosed herein may be applied to other embodiments without departing from the spirit or scope of this disclosure. While certain embodiments are described herein, these embodiments are presented by way of example only and do not limit the scope of this disclosure.

1. A power generator comprising:
a power generation component configured to generate a power waveform for transmission to a secondary component; and
a synchronization component configured to generate a synchronization signal for transmission to the secondary component, wherein the synchronization signal is formed with pulses having varying durations, and wherein a duration of a pulse in the synchronization signal conveys information to the secondary component about an event in the power waveform.

2. The power generator of claim 1, wherein the secondary component is a matching network.

3. The power generator of claim 1, wherein the duration of the pulse in the synchronization signal conveys information about a change in a state of the power waveform.

4. The power generator of claim 3, wherein a first pulse of a first duration in the synchronization signal indicates that the state is ending and that a next state in a same sequence of a same cycle of the power waveform is beginning.

5. The power generator of claim 4, wherein a second pulse of a second duration in the synchronization signal indicates that a last state of a particular repeating sequence is ending and that a first state in the same particular repeating sequence of the same cycle of the power waveform is beginning.

6. The power generator of claim 5, wherein a third pulse of a third duration indicates that the state is ending and that the next state in a first sequence of a next cycle of the power waveform is beginning.

7. The power generator of claim 1, wherein a threshold time of inactivity after a pulse is initiated signals the power is off.

8. A match network comprising:
an input configured to receive a power waveform from a primary component over a first signal path for transmission to the plasma processing apparatus; and
a synchronization component configured to receive a synchronization signal from the primary component over a second signal path, wherein the synchronization signal is formed with pulses having varying durations, and wherein a duration of a pulse in the synchronization signal conveys information to the match network about an event in the power waveform.

9. The match network of claim 8, wherein the primary component is a power generator.

10. The match network of claim 8, wherein the duration of the pulse in the synchronization signal conveys information about a change in a state of the power waveform.

11. The match network of claim 10, wherein a first pulse of a first duration in the synchronization signal indicates that the state is ending and that a next state in a same sequence of a same cycle of the power waveform is beginning.

12. The match network of claim 11, wherein a second pulse of a second duration in the synchronization signal indicates that a last state of a particular repeating sequence is ending and a first state in the same particular repeating sequence of the same cycle of the power waveform is beginning.

13. The match network of claim 12, wherein a third pulse of a third duration indicates that the state is ending and the next state in a first sequence of a next cycle of the power waveform is beginning.

14. The match network of claim 8, wherein a threshold time of inactivity after a pulse is initiated signals the power is off.

15. A power system comprising:
at least one power generator;
at least one match network, wherein
the power generator is configured to provide a power waveform to the match network; and
a primary synchronization module configured to generate a synchronization signal for transmission to the at least one of the power generator and/or the at least one match network, wherein the synchronization signal is formed with pulses having varying durations, wherein a duration of a pulse in the synchronization signal conveys information about an event in the power waveform.

16. The power system of claim 15, wherein the duration of the pulse in the synchronization signal conveys information about a change in a state of the power waveform.

17. The power system of claim 16, wherein a first pulse of a first duration in the synchronization signal indicates that the state is ending and that a next state in a same sequence of a same cycle of the power waveform is beginning.

18. The power system of claim 15, wherein the at least one generator includes the primary synchronization module.

19. The power system of claim 15, wherein the at least one match network includes the primary synchronization module.

20. The power system of claim 15, wherein a centralized controller includes the primary synchronization module.
